(19) United States
(12) Patent Application Publication
(10) Pub. No.: US 2015/0194293 A1
(43) Pub. Date: Jul. 9, 2015

(54) SPUTTERING TARGET

(71) Applicant: KOJUNDO CHEMICAL LABORATORY CO., LTD., Sakado-shi (JP)

(72) Inventors: Takahiro UNNO, Sakado-shi (JP); Takuma Shibayama, Sakado-shi (JP)

(73) Assignee: KOJUNDO CHEMICAL LABORATORY CO., LTD., Sakado-shi (JP)

(21) Appl. No.: 14/284,899

(22) Filed: May 22, 2014

(30) Foreign Application Priority Data
Jan. 6, 2014 (JP) 2014-000084

(51) Int. Cl. H01J 37/34

(52) U.S. Cl. CPC H01J 37/3429; H01J 2237/332

(57) ABSTRACT

A sputtering target is provided which contains MgO as a main component, can be used for DC sputtering, and allows a thin film having the same crystal structure as that of MgO to be deposited on a substrate by sputtering. It contains MgO which is a non-conductive oxide and TiO which is a conductive oxide. By causing the TiO content to be within a range of 20 to 60 mol %, the sputtering target is arranged to have conductivity as a whole.

### BACKGROUND OF THE INVENTION

1. Field of the Invention

The present invention relates to a sputtering target (hereinafter, may be simply referred to as a “target”) which contains MgO of a non-conductive oxide as a main component and can be used for direct-current (DC) sputtering.

2. Description of the Related Art

Conventionally, a sputtering method is known as a technique of depositing a thin film on a substrate. With this sputtering method, an inert gas element, such as argon etc., introduced in a vacuum vessel is energized into a plasma state. When this inert gas element in a plasma state collides with a target, a sputter particle is ejected from the target and accumulates on a substrate, to deposit a thin film.

As to the technique of depositing an oxide film or a nitride film among these sputtering methods, RF sputtering is common which employs a target of an oxide of an insulator or a nitride and uses a power supply for applying high frequency (RF). Further, the reactive sputtering is also known in which a reactant gas, such as oxygen or nitrogen, is introduced into a sputtering space and a film of a product of reaction with a component of the target is deposited.

However, there is a problem that the RF sputtering has a low film deposition rate and reduces the manufacturing efficiency of elements production, it is unsuitable for a large area substrate, the substrate is overheated, the production cost is high, etc.

On the other hand, although the film deposition rate is high, the reactive sputtering requires complicated processes, such as switching the reactant gases to be introduced, and has a problem that the deposited film is uneven, arcing is likely to take place, etc.

Thus, there is a need for a method of depositing a film of a non-conductive oxide and nitride efficiently and evenly.

Incidentally, when the target is conductive, it is possible to employ the DC sputtering which is the simplest sputtering method and uses a direct current (DC) power supply for applying electricity to the target.

Therefore, a conductive substance is added to a non-conductive substance to cause the target to be a conductive substance as a whole, which can be used as a target for the DC sputtering.

For example, International Publication WO 2013/005690 (Patent Literature 1) discloses that a MgO film can be deposited by sputtering a MgO target by DC power, which is mostly composed of MgO as an isolator and TiC, VC, WC or TiN as a conductive compound.

However, in the case where the conductive compound as described in Patent Literature 1 above is added to the target, there are the following problems. For example, since WC belongs to the hexagonal crystal system and has a WC type crystal structure, it is different from MgO which belongs to the cubic crystal system and has a NaCl type crystal structure. Furthermore, while a lattice constant of a crystal of MgO is 4.208 Å, that of WC is 2.906 Å, thus a misfit ratio (a ratio obtained by dividing a difference between lattice constants of both substances by the lattice constant of MgO) is as large as 30.9%. If the misfit ratio is large, when WC is added to MgO, there is a possibility that the crystal system and crystal structure of MgO may change and the property of MgO itself may change.

On the other hand, each of TiC, VC, and TiN which are the other conductive substances as described in Patent Literature 1 above belongs to the cubic crystal system, and has a NaCl type crystal structure, thus being the same as MgO.

However, the lattice constant of TiC is 4.318 Å and its misfit ratio to MgO is 2.61%; the lattice constant of VC is 4.118 A and its misfit ratio to MgO is 2.14%; both exceed 2%; it may cause a problem in matching with MgO in a thin film when a spattering is conducted with a MgO target containing TiC or VC to deposit the thin film.

On the other hand, the lattice constant of TiN is 4.249 Å and its misfit ratio with respect to MgO is 0.97% which is smaller than that of each of the above-mentioned conductive substances WC, TiC, and VC. Therefore, TiN may have no problem in matching with MgO.

Then, 75 mol % of MgO powder and 25 mol % of TiN powder were mixed and sintered. Using the thus processed target (see Comparative Example 2), DC sputtering was carried out to deposit a thin film on a substrate and its crystal orientation was measured with an X-ray diffraction apparatus (XRD). Its XRD chart is shown in FIG. 2.

It can be seen from the chart of FIG. 2 that different phases of Ti₂N, TiN_{0.43}, TiN_{0.6}, etc., appeared in addition to peaks of MgO or TiN. That is to say, those of crystal orientations different from the crystal orientation of MgO itself were generated. This shows that although addition of TiN allows the DC sputtering for the target containing MgO as the main component, a thin film having a crystal structure different from that of MgO is generated.

Therefore, there is a need for a target which allows the DC sputtering, has a misfit ratio with respect to MgO which is lower than that with respect to TiN, and can avoid changing the crystal structure of MgO itself in a thin film deposited on the substrate by sputtering.

### SUMMARY OF THE INVENTION

The present invention has been made in order to solve the above-mentioned technical problems and aims to provide a sputtering target which contains MgO as a main component, can be used for DC sputtering, and allows a thin film having the same crystal structure as that of MgO to be deposited on a substrate.

The sputtering target in accordance with the present invention is characterized by containing MgO which is a non-conductive oxide and TiO which is a conductive oxide and having conductivity as a whole.

By adding TiO to MgO, the whole target has conductivity and the target which allows the DC sputtering can be deposited.

It is preferable that the TiO content in the above-mentioned target is 20 to 60 mol %.

When the content is within the above-mentioned range, the stable DC sputtering can be performed.

The above-mentioned target has conductivity, and therefore can be suitably used for the DC sputtering.

Further, according to the above-mentioned target, a thin film having a NaCl type crystal structure which is the same crystal structure as that of MgO can be deposited by sputtering.

According to the sputtering target in accordance with the present invention, even the target having MgO of a non-conductive oxide as the main component allows the DC sputtering and a thin film having the same crystal structure as that of MgO can be deposited on a substrate by sputtering.

### BRIEF DESCRIPTION OF THE DRAWING

FIG. 1 is an XRD chart of a thin film deposited by sputtering a target prepared by adding TiO powder to MgO powder.

FIG. 2 is an XRD chart of a thin film deposited by sputtering a target prepared by adding TiN powder to MgO powder.

### DESCRIPTION OF THE PREFERRED EMBODIMENTS

Hereinafter, the present invention will be described in detail.

A sputtering target in accordance with the present invention is characterized by comprising MgO which is a non-conductive oxide and TiO which is a conductive oxide and having conductivity as a whole.

Thus, as a conductive substance, TiO having a low misfit ratio to MgO is added to the target containing MgO as a main component, so that the target has conductivity as a whole and it is possible to obtain a target which allows DC sputtering.

Further, in the present invention, the thin film obtained by sputtering this target and deposited on the substrate by using TiO as a conductive substance added to MgO may have the same crystal structure as that of MgO.

TiO is of cubic crystal system, its crystal structure is the NaCl type crystal structure, and its lattice constant is 4.172 Å. Therefore, its misfit ratio with respect to MgO is 0.86%, smaller than those of TiC, VC, WC and TiN as described above. Further, since it is an oxide like MgO and matched with MgO well, it is thought that the crystal structure of the thin film deposited is the same as that of the crystal structure of MgO.

Furthermore, TiO has a specific resistance of 0.31 mΩ·cm, which is higher than that (61 μΩ·cm) of TiC, that (78 μΩ·cm) of VC, that (19 μΩ·cm) of WC, and that (40 μΩ·cm) of TiN. However, in the case where it is added to MgO which is a non-conductive substance, it may be caused to be conductive as a whole. Thus, it is confirmed that the more additive amount of TiO, the lower the specific resistance of the target.

Therefore, the target in accordance with the present invention can be suitably used for the DC sputtering.

It is preferable that the TiO content in the above-mentioned target is 20 to 60 mol %.

When the TiO content is less than 20 mol %, it is difficult to cause the specific resistance of the whole target to be 0.1 Ω·cm or less which is a reference for stable DC sputtering.

On the other hand, MgO has a thermal conductivity of 58.8 W/(m·K) which is higher than those of other oxides, and TiO has a thermal conductivity of 8.38 W/(m·K) which is lower than that of MgO. For this reason, as an amount of TiO added to MgO is increased, the thermal conductivity of a thin film deposited by sputtering the target decreases with increasing amount of TiO.

In the case where the TiO content exceeds 60 mol %, the thermal conductivity of the thin film deposited by sputtering the target is around 27 W/(m·K) or less, i.e. approximately less than ½ of that of MgO, this is not preferred in practice.

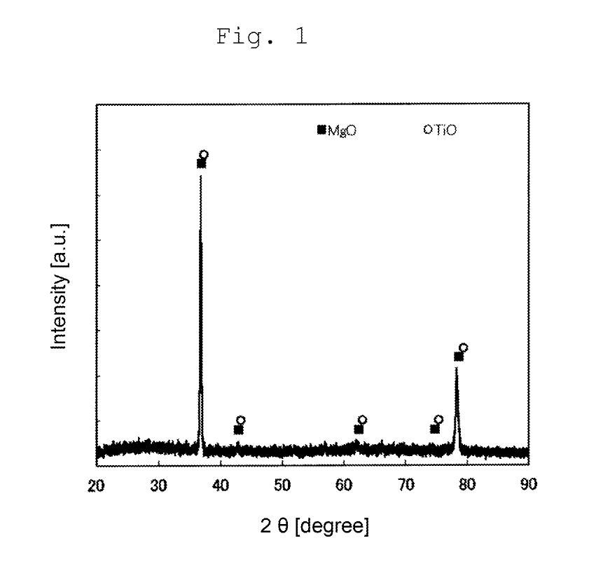

Using a target obtained in such a way that 45 mol % of MgO powder and 55 mol % of TiO powder were mixed, sintered, and processed, the DC sputtering was carried out to deposit a thin film on a substrate, and XRD measurement was performed. FIG. 1 is a chart showing the results.

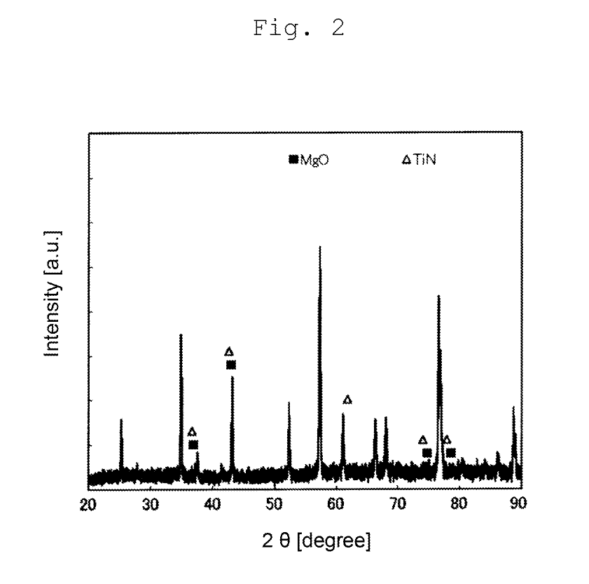

From FIG. 1, it is confirmed that, as for the crystal structure of this thin film, the NaCl type crystal structure is kept perfect. In the case where TiN is added to MgO, as described above, the crystal structure other than the NaCl type crystal structure which is the crystal structure of MgO appears (see FIG. 2). Therefore, it can be said that adding TiO to MgO is better than adding TiN in respect of crystallinity.

Thus, according to the target in accordance with the present invention, the thin film having the same NaCl type crystal structure as that of MgO can be deposited by sputtering.

In addition, although the method for manufacturing the target in accordance with the present invention is not particularly limited, it can be produced, for example, by sintering the mixed powder obtained by adding TiO powder to MgO powder as shown also in the following Examples.

Here, by “sintering” we mean heating and bonding powders at a high temperature (below melting point) by way of the hot pressing process, the pressureless sintering process, the HIP process (hot isostatic pressing process), the SPS process (spark plasma sintering process), etc.

### EXAMPLE

Hereinafter, the present invention will be described more particularly with reference to Examples, however the present invention is not limited to the following Examples.

### Example 1

TiO powder was added to MgO powder to have a concentration of 20 mol %. The mixed powder was milled for 4 hours in a ball mill, and the resulting mixture was sintered in a hotpress furnace to make a target having a diameter of 3 inches and a thickness of 5 mm.

Specific resistance of this target was measured by the four-probe method of resistivity measurement to give 0.09 Ω·cm.

Using this target, DC sputtering was performed in a sputtering apparatus at an output of 50 W, using quartz glass as a sputtering substrate. As a result, there was no abnormal appearance, such as arcing or the like, and the sputtering was performed stably with a film deposition rate of 1.9 nm/min.

Further, the thin film deposited on the quartz glass substrate by the above-mentioned sputtering was subjected to XRD measurement. As a result, two clear X-ray diffraction peaks were obtained, and it was confirmed that the diffraction angles were in agreement with the diffraction angles of the reference peaks of MgO.

### Example 2

A concentration of TiO powder was set as 50 mol %, and other conditions were the same as those in Example 1. A target was produced and evaluated.

A specific resistance of this target was 3.2 mΩ·cm.

Further, there were no abnormalities, such as arcing or the like, and the sputtering was performed stably with a film deposition rate of 1.9 nm/min.

Furthermore, in XRD measurement carried out for the thin film deposited by sputtering, two clear X-ray diffraction peaks were obtained, and it was confirmed that the diffraction angles were in agreement with the diffraction angles of the reference peaks of MgO.

### Comparative Example 1

MgO powder was sintered as it was in the hotpress furnace to make a target having a diameter of 3 inches and a thickness of 5 mm. The target was evaluated similarly to Example 1.

Since a specific resistance of this target was substantially infinite, it was not possible to perform the DC sputtering at an output of 50 W in the sputtering apparatus.

In addition, it was subjected to RF sputtering. As a result, there was also no abnormal appearance, such as arcing or the like, and the sputtering was performed stably with a film deposition rate of 0.6 nm/min.

Further, in XRD measurement carried out for the thin film deposited by the above-mentioned RF sputtering, several clear X-ray diffraction peaks were obtained. It was confirmed that the diffraction angles were in agreement with the diffraction angles of the reference peaks of MgO.

### Comparative Example 2

TiN powder was added to MgO powder to have a concentration of 25 mol %. The mixed powder was milled for 4 hours in the ball mill, and the resulting mixture was sintered in the hotpress furnace to produce a target having a diameter of 3 inches and a thickness of 5 mm. The target was evaluated similarly to Example 1.

A specific resistance of this target was 15 mΩ·cm.

Further, there was no abnormal appearance, such as arcing or the like, and the sputtering was performed stably with a film deposition rate of 1.5 nm/min.

Furthermore, in XRD measurement carried out for the thin film deposited by sputtering, a lot of clear X-ray diffraction peaks were obtained. A part of the diffraction angles were in agreement with the diffraction angles of the reference peaks of MgO, but many peaks were different from the reference peaks of MgO.

What is claimed is:

1. A sputtering target, comprising MgO which is a non-conductive oxide and TiO which is a conductive oxide and having conductivity as a whole.

2. A sputtering target as claimed in claim 1, wherein TiO content is 20 to 60 mol %.

3. A sputtering target as claimed in claim 1, characterized by being for direct-current sputtering.

4. A sputtering target as claimed in claim 2, characterized by being for direct-current sputtering.

5. A sputtering target as claimed in claim 1, wherein a thin film having a NaCl type crystal structure is deposited by sputtering.

6. A sputtering target as claimed in claim 2, wherein a thin film having a NaCl type crystal structure is deposited by sputtering.

7. A sputtering target as claimed in claim 3, wherein a thin film having a NaCl type crystal structure is deposited by sputtering.

8. A sputtering target as claimed in claim 4, wherein a thin film having a NaCl type crystal structure is deposited by sputtering.
